(19) United States
(12) Patent Application Publication
(10) Pub. No.: US 2025/0370033 A1
(43) Pub. Date: Dec. 4, 2025

(54) Optical Semiconductor Integrated Circuit

(71) Applicant: Nippon Telegraph and Telephone Corporation, Tokyo (JP)

(72) Inventors: Masayuki Takahashi, Musashino-shi, Tokyo (JP); Yuichiro Ikuma, Musashino-shi, Tokyo (JP); Yosuke Hinakura, Musashino-shi, Tokyo (JP)

(21) Appl. No.: 18/874,034

(22) PCT Filed: Jun. 15, 2022
(86) PCT No.: PCT/JP2022/024035

§ 371 Date: Dec. 11, 2024

(51) Int. Cl. G01R 31/28; G01R 1/073; G01R 31/311; G02F 1/21; H10F 39/10

(52) U.S. Cl. CPC G01R 31/2884; G01R 31/311; G02F 1/212; H10F 39/103; G01R 1/07342

(57) ABSTRACT

An optical semiconductor integrated circuit of the present disclosure realizes efficient wafer level testing by including electrical input/output terminals disposed around a chip and optical input/output terminals in the periphery in which electrical input/output terminals are not disposed. The optical semiconductor integrated circuit chip includes a plurality of electrical input/output terminals in at least one peripheral portion of a chip region. The electrical input/output terminals may be disposed in a U shape around the three sides. The optical semiconductor integrated circuit chip further includes an optical input/output terminal on one side on which an electrical input/output terminal is not disposed. The optical input/output terminal may be a grating coupler formed on a substrate.

### TECHNICAL FIELD

The present invention relates to an optical semiconductor integrated circuit, and more specifically to a terminal disposition which enables optical and electrical testing.

### BACKGROUND ART

In recent years, the range of application of optical communication modules and devices has not been limited to long-distance communication, and there has also been use for links between data centers, between mobile phone base stations, between edge routers, and the like and the demand for them is increasing. Automatic wafer-level testing is also required for optical semiconductor integrated circuit chips including optical circuits used in optical communication modules to eliminate defective chips before the module assembly process and increase yield.

For semiconductor integrated circuits which do not include optical circuits, automatic wafer-level testing is widely performed using low-cost cantilever probe cards. In wafer-level automatic testing of semiconductor integrated circuit chips with several tens to hundreds of terminals, it is common to use cantilever probe cards that can be produced at low cost (NPL 1, NPL 2).

### CITATION LIST

### Non Patent Literature

[NPL 1] H. Iwai, A. Nakayama, N. Itoga and K. Omata, “Cantilever type probe card for at-speed memory test on wafer,” 23rd IEEE VLSI Test Symposium (VTS'05), 2005, pp. 85-89, doi: 10.1109/VTS.2005.34.

[NPL 2] Seiken Co., Ltd., Features and Comparison of Probe Cards (Vertical type/Cantilever type), [online], [Retrieved Jun. 1, 2022], Internet <URL: https://www.seiken.co.jp/semiconductor/probecard.html>

[NPL 3] C. B. Sia et al., “Test Setup Optimization and Automation for Accurate Silicon Photonics Wafer Acceptance Production Tests,” 2020 IEEE 33rd International Conference on Microelectronic Test Structures (ICMTS), 2020, pp. 1-4, doi: 10.1109/ICMTS48187.2020.9107907.

### SUMMARY OF INVENTION

### Technical Problem

In automatic wafer-level testing of optical semiconductor integrated circuits included in optical communication devices, it is necessary to perform optical testing in addition to electrical testing. For optical testing, optical input/output terminals such as grating couplers are disposed on the chip and used as optical input/output probes. Optical semiconductor integrated circuits require testing using an optical input/output probe and an electrical probe simultaneously. In the case of a general cantilever type probe card, due to the structure thereof, it is not possible to provide a region for contacting the optical input/output probe with the optical semiconductor integrated circuit wafer and automatic wafer level testing cannot be performed. Testing methods compatible with optical probes also do not have chip terminal layouts which correspond to electrical probe cards. Thus, only DC probes and RF probes can be used and the number of electrical terminals is limited to about 10 to 20 (NPL 3).

### Solution to Problem

An aspect of the present invention is an optical semiconductor integrated circuit having an optical circuit and an electrical circuit including: a plurality of electrical input/output terminals disposed around at least one periphery of a chip region; and one or more optical input/output terminals disposed around one periphery in which the plurality of electrical input/output terminals are not disposed.

### Advantageous Effects of Invention

According to the present invention, it is possible to realize efficient wafer-level testing of optical semiconductor integrated circuits.

### BRIEF DESCRIPTION OF DRAWINGS

FIG. 1 is a diagram for explaining a terminal disposition for automatic testing in a semiconductor integrated circuit.

FIG. 2 is a diagram showing how a semiconductor integrated circuit is measured with a probe card.

FIG. 3 is a diagram showing a terminal disposition configuration of an optical semiconductor integrated circuit according to a first embodiment of the present disclosure.

FIG. 4 is a diagram showing a configuration of a probe card suitable for the optical semiconductor integrated circuit.

FIG. 5 is a diagram showing a terminal disposition configuration of an optical semiconductor integrated circuit according to a second embodiment of the present disclosure.

FIG. 6 is a diagram showing a terminal disposition configuration of an optical semiconductor integrated circuit according to a third embodiment of the present disclosure.

FIG. 7 is a diagram showing a terminal disposition configuration of an optical semiconductor integrated circuit according to a fourth embodiment of the present disclosure.

FIG. 8 is a diagram for explaining optical measurement using an array type optical input/output probe.

### DESCRIPTION OF EMBODIMENTS

An optical semiconductor integrated circuit of the present disclosure realizes efficient wafer level testing by including electrical input/output terminals disposed around the chip and optical input/output terminals in the periphery in which electrical input/output terminals are not disposed. A terminal disposition which enables efficient automatic wafer-level testing of optical semiconductor integrated circuits is proposed. In the following description, first the disposition of electrical terminals for automatic testing in a semiconductor integrated circuit will be explained, and then the disposition of electrical input/output terminals and optical input/output terminals in the optical semiconductor integrated circuit of the present disclosure will be explained.

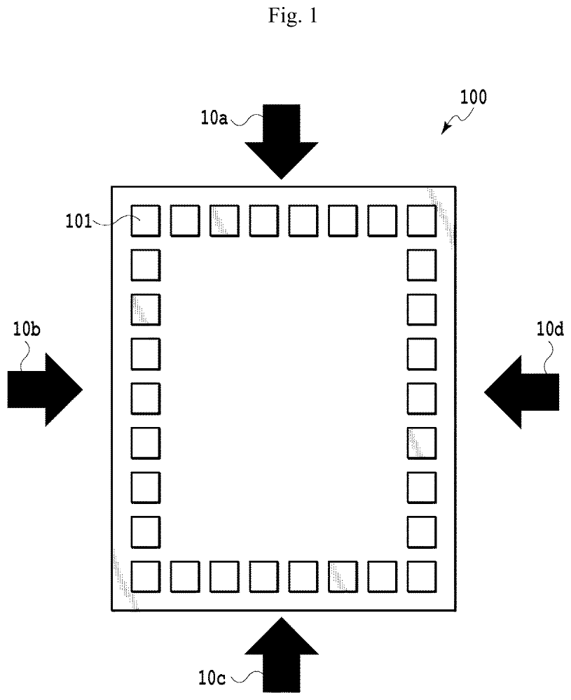

FIG. 1 is a diagram for explaining a terminal disposition for automatic testing in a semiconductor integrated circuit. A semiconductor integrated circuit chip 100 has a plurality of electrical input/output terminals 101 disposed around a chip region to support automatic testing. These terminals 101 are also called pads and a corresponding cantilever which will be described later is in contact with each pad. The cantilever enters from outside the chip region in four directions 10a to 10d corresponding to the four sides of the chip region and comes into contact with the electrical input/output terminals.

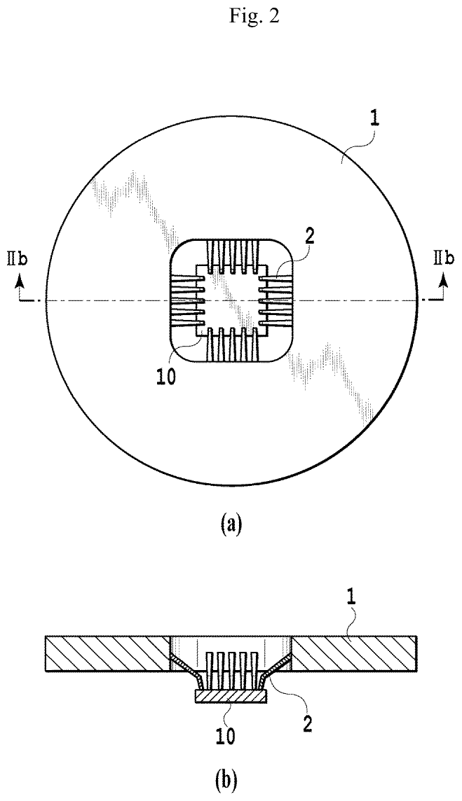

FIG. 2 is a diagram showing how a semiconductor integrated circuit is measured with a probe card. The probe card is a device used for electrical testing of LSI chips and functions as an interface through which an LSI tester that is a measuring device is electrically connected to the electrical input/output terminals, that is, pads 101 located in the chip region of the wafer. In FIG. 2, the upper side shows the top surface of the probe card 1 which is testing a chip region 10 of a semiconductor integrated circuit and the lower side shows a cross section near the chip region of the probe card 1 which is being tested. In FIG. 2, only a single semiconductor integrated circuit on a wafer is extracted and drawn as the chip region 10. Note that, since the probe card performs wafer level testing, it is tested before it is cut into chips.

The probe card 1 has a large number of probes (probes) and presses the probes onto pads to establish electrical contact. As shown in FIG. 2, cantilever type probes are widely used. In addition, by pressing a plurality of cantilevers 2 against the pads with a predetermined pressure, a stable electrical connection with the electrical circuit inside the chip can be obtained. The entire wafer is moved using a transport part (not shown) which holds the wafer and different chip regions are sequentially inspected.

The configuration in which the chip region 10 of a semiconductor integrated circuit having the terminal disposition as shown in FIG. 1 is inspected using the cantilever probe card 1 shown in FIG. 2 is not provided so that measurements can be performed simultaneously using the optical input and output terminals of the optical semiconductor integrated circuit. As the optical input/output terminal, it is necessary to use a tipped fiber, a lensed fiber, a single mode fiber, a polarization maintaining fiber, or a fiber array of a combination thereof as an optical input/output probe.

The optical semiconductor integrated circuit of the present disclosure provides a terminal configuration which allows simultaneous electrical measurement using a widely used probe card and optical measurement using an optical input/output terminal and an optical input/output probe.

### First Embodiment

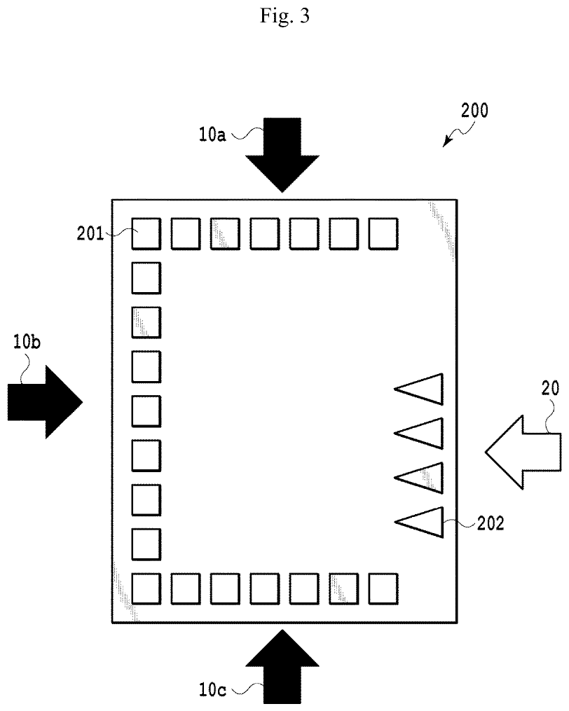

FIG. 3 is a diagram showing a terminal disposition configuration of an optical semiconductor integrated circuit according to a first embodiment of the present disclosure. An optical semiconductor integrated circuit chip 200 is an integrated circuit which includes both optical circuit elements and electric circuit elements and is, for example, produced on a Si substrate wafer. The optical semiconductor integrated circuit chip 200 shown in FIG. 3 shows the top surface of a single chip region, and during wafer level testing, is one region on a wafer before being cut into individual chips. There are no limitations to the functions realized by the optical semiconductor integrated circuit chip 200 and all of the following drawings show terminals necessary for wafer-level testing.

The optical semiconductor integrated circuit chip 200 includes a plurality of electrical input/output terminals 201 around at least one of the chip regions. The electrical input/output terminals may be disposed in a U shape around the three sides as shown in FIG. 3. The optical semiconductor integrated circuit chip 200 further includes an optical input/output terminal 202 on one side on which an electrical input/output terminal is not disposed. The optical input/output terminal 202 may be a grating coupler formed on a substrate. The grating coupler is connected from a portion in which a rectangular grating is formed to a waveguide with a width of approximately 350 to 600 nm through a tapered waveguide expansion region. This waveguide is connected to optical circuit elements such as an optical modulator and a photodiode in the chip and allows light to be input and output in the grating using an external optical input/output probe. In the drawings after FIG. 3, the grating region and the waveguide enlarged region are schematically shown as triangles.

In the probe card 1 shown in FIG. 2, the cantilever is inserted from four directions such as upward, downward, leftward, and rightward directions. On the other hand, if the terminals are disposed as shown in FIG. 3, the cantilever can enter the electrical input/output terminals disposed in a U shape from three directions 10a to 10c. At the same time, an optical input/output probe is inserted in a direction 20 toward one periphery of the optical semiconductor integrated circuit 200 from outside the chip region and optically coupled to the optical input/output terminal 202 to perform optical testing.

Therefore, the optical semiconductor integrated circuit of the present disclosure is an optical semiconductor integrated circuit 200 having an optical circuit and an electric circuit and can be realized as an optical semiconductor integrated circuit having a plurality of electrical input/output terminals 201 disposed around at least one periphery of the chip area and one or more optical input/output terminals 202 disposed around one periphery in which the plurality of electrical input/output terminals are not disposed.

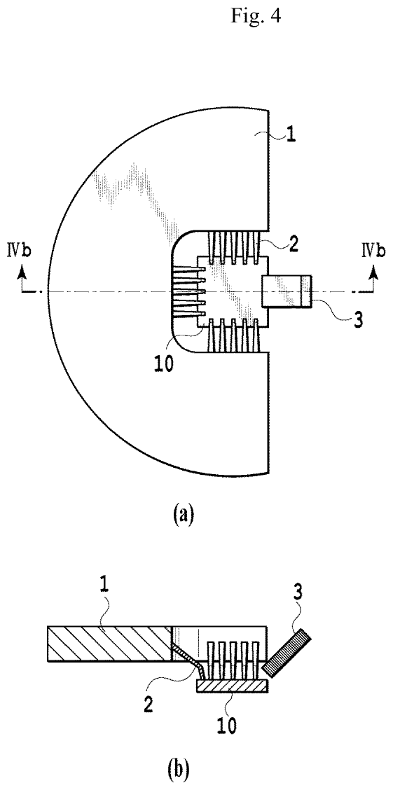

FIG. 4 is a diagram showing a configuration of a probe card suitable for the optical semiconductor integrated circuit. By cutting off one side of the probe card 1 for the semiconductor integrated circuit shown in FIG. 2, the optical probe 3 can penetrate into the chip region through the cut region. Testing using the optical input/output probe 3 is made possible by adjusting the probe card into a U shape in which three sides of the optical semiconductor integrated circuit can be accommodated. As shown in FIG. 3, by providing electrical input/output terminals disposed on a maximum of three sides and an optical input/output terminal 202 on one side on which electrical input/output terminals are not disposed, automatic wafer-level testing of large-scale optical semiconductor integrated circuits with over 100 electrical terminals becomes possible. For example, it is suitable for an optical semiconductor integrated circuit including a large number of optical transmitting/receiving circuits which are incorporated into an optical communication module.

FIG. 3 shows an example in which electrical input/output terminals are disposed around three peripheries and an optical input/output probe 202 is provided around the remaining one. The position of the optical input/output probe is not limited to this, and as long as the electrical input/output terminals are disposed around the two sides corresponding to directions 10a and 10b, the optical input/output terminal can also be provided on the side corresponding to the direction 10c. In this case, the optical input/output probe will be inserted in the direction 10c in FIG. 3. As another example, if electrical input/output terminals are disposed only on one periphery corresponding to direction 10b, optical input/output terminals can be provided on the side corresponding to the direction 10a. In this case, the optical input/output probe will be inserted in the direction 10a.

Therefore, the electrical input/output terminals 201 do not need to be provided on all three sides of the chip periphery as shown in FIG. 3. Furthermore, the electrical input/output terminals may be present not only in the peripheral region of the chip as shown in FIG. 3 but also inside the chip region. The electrical input/output terminals include terminals required for testing and installation terminals required at the time of performing modularization through installation of them in device substrates or the like. In addition, the terminals used only during installing may be disposed at any position.

### Second Embodiment

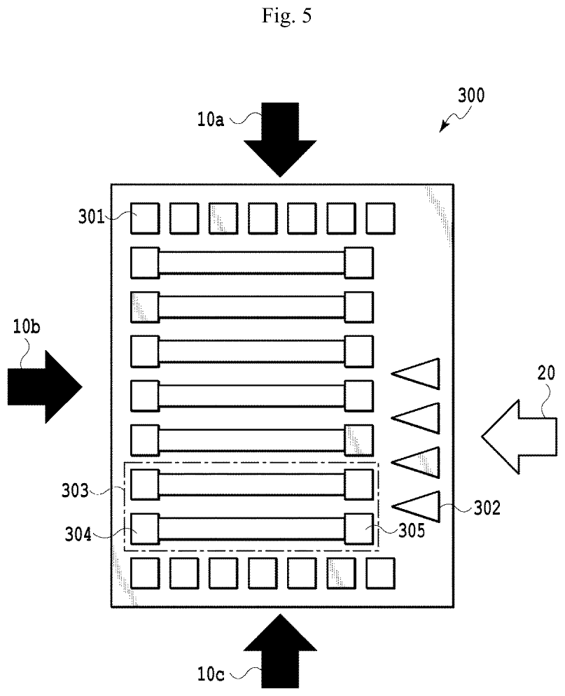

FIG. 5 is a diagram showing a terminal disposition configuration of an optical semiconductor integrated circuit according to a second embodiment of the present disclosure. An optical semiconductor integrated circuit 300 of the second embodiment includes a plurality of Mach-Zehnder interferometer (MZI) type modulators as optical circuits. FIG. 5 schematically shows an example including four MZI modulators 303. The MZI modulator includes a modulation electrode formed between a high frequency electrical signal input terminal 304 and a high frequency electrical signal output terminal 305.

The optical semiconductor integrated circuit 300 includes a plurality of electrical input/output terminals on at least one periphery, and in the example of FIG. 5, a plurality of electrical input/output terminals 301 on three sides. In the electrical input/output terminals, a high frequency electrical signal input terminal 304 of the MZI modulator is disposed around one of them. An optical input/output terminal 302 is further provided in one periphery in which an electrical input/output terminal is not disposed. The optical input/output terminal 302 may be a grating coupler formed on a substrate.

By disposing the high frequency signal input terminal 304 of the electrode of the MZI type modulator on the periphery of the chip, when the chip is installed in a module substrate or the like, a physical distance from the MZI modulator drive circuit can be shortened. By shortening the connection distance, it is possible to reduce high frequency loss due to the connection between the drive circuit and the MZI modulator and improve the high frequency performance of the modulator.

In the optical semiconductor integrated circuit 300, cantilevers can be inserted into the electrical input/output terminals disposed in a U shape from three directions 10a to 10c. An optical input/output probe is inserted in the direction 20 from outside the chip region toward one periphery of the optical semiconductor integrated circuit 300 and optically coupled to the optical input/output terminal 302 to perform optical testing. As in the optical semiconductor integrated circuit of the first embodiment, since the optical input/output terminal 302 is provided in one periphery in which an electrical input/output terminal is not disposed, automatic wafer level testing of an optical semiconductor integrated circuit including an MZI type modulator can be performed.

The electrical input/output terminals 301 and 304 do not need to be located on all three sides of the chip periphery. The electrical input/output terminals may be present inside the chip. In an optical semiconductor integrated circuit, electrical input/output terminals include terminals necessary for testing and installation terminals necessary for assembly when actually modularizing and terminals used only for installation may be disposed at any position. Since the terminal on the high frequency signal output side of the MZI modulator is an installation terminal which does not require probing during testing, it may be disposed near the optical input/output terminal 302 such as a grating coupler.

### Third Embodiment

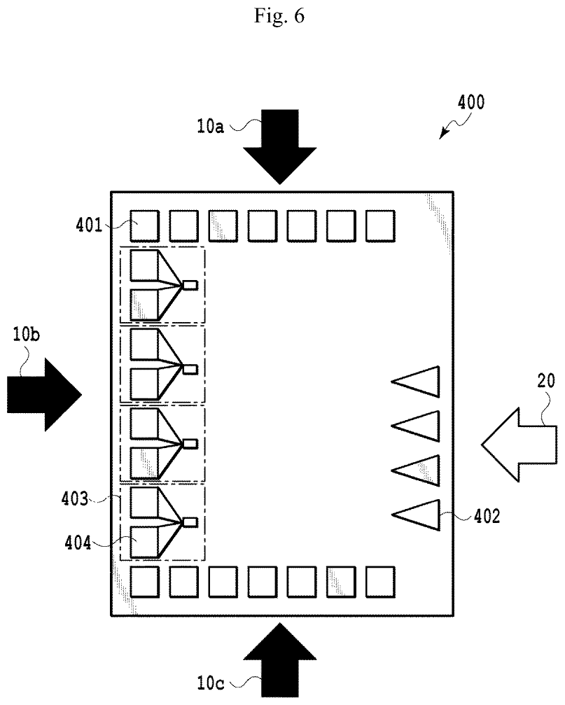

FIG. 6 is a diagram showing a terminal disposition configuration of an optical semiconductor integrated circuit according to a third embodiment of the present disclosure. A case in which an optical semiconductor integrated circuit 400 according to the third embodiment includes a plurality of photodiodes as optical circuits is shown. FIG. 6 schematically shows an example including four photodiodes 403. Each of the photodiode 403 includes a photodiode element 405 and a high frequency electrical signal output terminal 404 from which a detection signal is extracted.

The optical semiconductor integrated circuit 400 includes a plurality of electrical input/output terminals on at least one periphery, and in the example of FIG. 6, a plurality of electrical input/output terminals 401 on three sides. In these electrical input/output terminals, a photodiode high frequency electrical signal output terminal 404 is disposed at the periphery of one side. An optical input/output terminal 402 is further provided on one side on which an electrical input/output terminal is not disposed. The optical input/output terminal 402 may be a grating coupler formed on a substrate.

By disposing the high frequency signal output terminal 404 of the photodiode electrode around the chip, when the chip is installed in a module or the like, a physical distance from the photodiode to the amplification circuit for the electrical signal output can be shortened. By shortening the electrical wiring, high frequency loss due to the connection between the amplifier circuit and the photodiode can be reduced and high frequency performance can be improved.

In the optical semiconductor integrated circuit 400, cantilevers can be inserted into the electrical input/output terminals disposed in a U shape from three directions 10a to 10c. An optical input/output probe can be inserted in the direction 20 from outside the chip region toward one periphery of the optical semiconductor integrated circuit 400 and optically coupled to the optical input/output terminal 402 to perform optical testing. As in the optical semiconductor integrated circuit of the first embodiment and the second embodiment, since the optical input/output terminal 402 is provided on one side on which an electrical input/output terminal is not disposed, automatic wafer level testing of an optical semiconductor integrated circuit including a plurality of photodiodes can be performed.

The electrical input/output terminals do not need to be located on all three sides of the chip periphery. The electrical input/output terminals may be present inside the chip. In optical semiconductor integrated circuits, electrical input/output terminals include terminals required for testing and installation terminals required at the time of performing actual modularization and terminals used only during installation may be disposed at any position.

### Fourth Embodiment

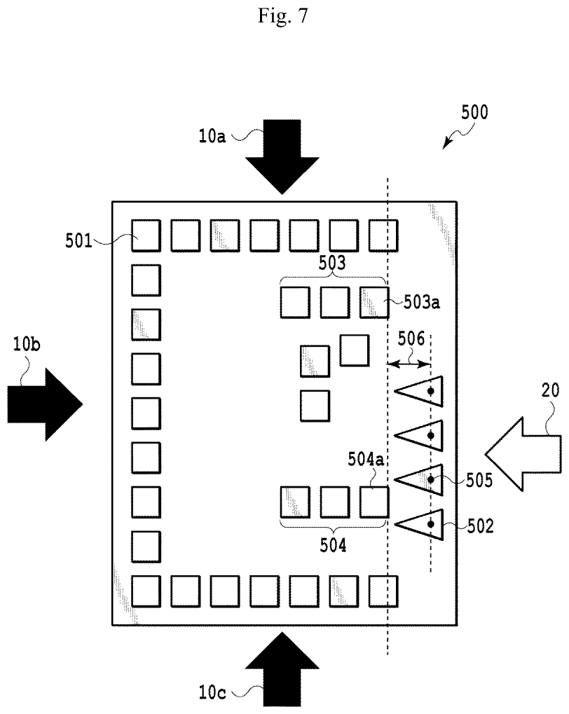

FIG. 7 is a diagram showing a terminal disposition configuration of an optical semiconductor integrated circuit according to a fourth embodiment of the present disclosure. The optical semiconductor integrated circuit 500 of the fourth embodiment shows a configuration example in which an electrical input/output terminal and an optical input/output terminal are close to each other.

The optical semiconductor integrated circuit 500 includes a plurality of electrical input/output terminals on at least one periphery, and in the example of FIG. 7, a plurality of electrical input/output terminals 501 on three sides. Furthermore, an electrical input/output terminal 504a disposed parallel to the electrical input/output terminal on the upper side and an electrical input/output terminal 504 disposed parallel to the electrical input/output terminal on the lower side are provided further inside the chip region. By leaving a certain distance between the two rows of electrical input/output terminals, the cantilever can enter the two rows simultaneously or separately from directions 10a and 10c. The optical semiconductor integrated circuit 500 further includes an optical input/output terminal 502 on one side on which an electrical input/output terminal is not disposed. The optical input/output terminal 502 may be a grating coupler formed on a substrate.

Also in the optical semiconductor integrated circuit 500 of the embodiment, an optical input/output probe can be inserted in the direction 20 from outside the chip region and optically coupled to the optical input/output terminal 502 to perform optical testing. In the terminal disposition of the optical semiconductor integrated circuit 500, a distance between the optical input/output terminal 502 and adjacent electrical input/output terminals 503a, 504a becomes an issue.

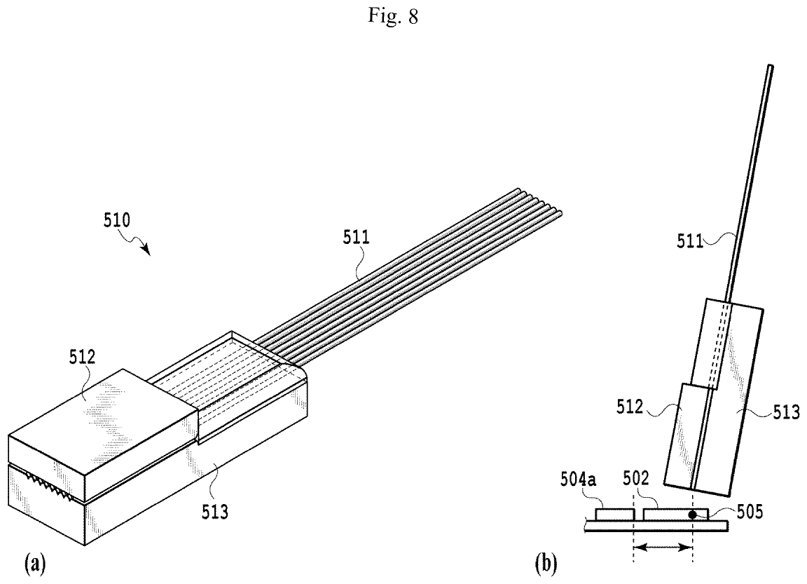

FIG. 8 is a diagram for explaining optical measurement using an array type optical input/output probe. FIG. 8(a) shows a structure of an array type optical input/output probe 510. The optical input/output probe 510 includes a base member 513 in which a plurality of grooves are formed at intervals of the fiber array and a lid member 512 which has a fiber array 511 disposed therebetween and fixes the fiber array 511. The lid member 512 needs to have a thickness of at least about 200 μm.

FIG. 8(b) shows how an optical measurement is performed using an array type optical input/output probe 510. FIG. 8(b) shows a cross section perpendicular to a wafer substrate including the optical input/output terminal 502 in FIG. 7 and an electrical input/output terminal 504a for testing adjacent to the optical input/output terminal 502. Here, as the optical input/output terminal 502, a grating coupler prepared using a silicon photonics technique using a silicon substrate will be considered. The beam output from such the grating coupler 502 has a wavelength of 1550 μm in the communication wavelength band, and when the surface height from the wafer is 150 μm, it has a spread of about 100 μm in the horizontal direction as shown in FIG. 8(b). That is to say, if the adjacent electrical input/output terminal 504a is approximately 250 μm away from the optical input/output center point 505 which is an extension of the center of the core of the optical input/output probe 510, the cantilever can be inserted without interference. This is because, at the time of scanning the position of the optical input/output probe 510 to obtain maximum optical coupling with the beam output from the grating coupler, a space margin of about 50 μm is required in the direction in which the electrical input/output terminal 504a exists.

Referring to FIG. 7 again, by disposing each terminal so that the distance from the coupling center position 505 of the optical input/output terminal 502 to the nearest electrical input/output terminal is 250 μm or more, wafer level automatic testing of optical semiconductor integrated circuits can be performed without interference between the cantilever probe and the optical output probe.

Even in the optical semiconductor integrated circuit of this embodiment, the electrical input/output terminals do not need to be located on all three sides of the chip periphery. The electrical input/output terminals may be present inside the chip. The electrical input/output terminals include terminals necessary for testing and installation terminals necessary at the time of performing actual modularization. In addition, the terminals used only during installing may be disposed at any position.

### INDUSTRIAL APPLICABILITY

The present invention can be used for optical communication.

1. An optical semiconductor integrated circuit having an optical circuit and an electrical circuit, comprising:
a plurality of electrical input/output terminals disposed around at least one periphery of a chip region; and
one or more optical input/output terminals disposed around one periphery in which the plurality of electrical input/output terminals are not disposed.

2. The optical semiconductor integrated circuit according to claim 1, wherein the optical circuit includes a Mach-Zehnder interferometer type modulator, and
the high frequency signal input terminals of the Mach-Zehnder interferometer type modulator are included in the plurality of electrical input/output terminals.

3. The optical semiconductor integrated circuit according to claim 1, wherein the optical circuit includes a photodiode, and
the high frequency signal output terminals of the photodiode are included in the plurality of electrical input/output terminals.

4. The optical semiconductor integrated circuit according to claim 1, wherein a distance between the electrical input/output terminal closest to the one or more optical input/output terminals among the electrical input/output terminals disposed along a periphery orthogonal to the one periphery on which the one or more optical input/output terminals are disposed and an optical input/output point of the optical input/output terminal is 250 μm or more.

5. The optical semiconductor integrated circuit according to claim 1, wherein the optical input/output terminal is a grating coupler which can input and output light toward the outside of the chip region.

6. The optical semiconductor integrated circuit according to claim 1, which is prepared using a silicon photonics technique.
